(19) United States
(12) Patent Application Publication
(10) Pub. No.: US 2012/0080725 A1
(43) Pub. Date: Apr. 5, 2012

(54) VERTICAL TRANSISTOR MEMORY ARRAY

(75) Inventors: Peter Nicholas Manos, Eden Prairie, MN (US); Young Pil Kim, Eden Prairie, MN (US); Hyung-Kyu Lee, Edina, MN (US); Yongchul Ahn, San Jose, CA (US); Jinyoung Kim, Edina, MN (US); Antoine Khoueir, Apple Valley, MN (US); Brian Lee, Boston, MA (US); Dadi Setiadi, Edina, MN (US)

(73) Assignee: SEAGATE TECHNOLOGY LLC, Scotts Valley, CA (US)

(21) Appl. No.: 12/894,405

(22) Filed: Sep. 30, 2010

(51) Int. Cl. H01L 27/08; H01L 21/02

(52) U.S. Cl. 257/208; 438/382; 257/329; 257/E21.004; 257/E27.046

(57) ABSTRACT

A method includes providing a semiconductor wafer having a plurality of pillar structures extending orthogonally from the semiconductor wafer. An electrically conducting interconnect element is deposited onto at least selected vertical pillar transistors and a non-volatile variable resistive memory cell is deposited onto the electrically conducting interconnect layer to form a vertical transistor memory array.

### BACKGROUND

Solid state memories (SSMs) provide an efficient mechanism for storing and transferring data in a wide variety of applications, such as hand-held portable electronic devices. Individual memory cells within such memories can be volatile or non-volatile, and can store data by the application of suitable write currents to the cells to store a sequence of bits. The stored bits can be subsequently read during a read access operation by applying suitable read currents and sensing voltage drops across the cells.

Some SSM cell configurations employ a memory element coupled to a channel based switching device such as a metal oxide semiconductor field effect transistor (MOSFET). The switching device provides selective access to the memory element during read and write operations. Examples of memory cells with this type of memory element-switching device arrangement include, but are not limited to, volatile dynamic random access memory (DRAM), non-volatile resistive random access memory (RRAM), and non-volatile spin-torque transfer random access memory (STRAM).

While operable, a limitation with the use of MOSFETs and other types of switching devices in a memory cell is the areal extent (size) of such devices. A horizontal MOSFET layout is often used in which the associated drain and source regions are placed adjacent one another in a base substrate, with the channel region extending horizontally therebetween. The memory element is formed above either the source or the drain.

Horizontal MOSFETs may require a minimum size of about 4 F² where F is the minimum feature dimension of the associated manufacturing process (e.g., F=70 nm, etc.). Since this is significantly larger than the areal size of many types of memory elements, the switching device size can be a limiting factor in achieving greater areal densities in a memory array.

The amount of current needed to operate STRAM memory elements can be quite large, of the order of 500-1000 uA. Because the horizontal MOSFET (i.e., select device) conducts current primarily in the surface region of the device, its conductivity is limited, often requiring a large MOSFET to be used in order to delivered sufficient current to program the STRAM cell. Larger MOSFET devices lead to larger STRAM cell areas, and increase die size and product cost. Also, horizontal select devices have certain alignment tolerances built into their design, to avoid device failures, this adds parasitic resistance and capacitance which slows down the operation of the STRAM, as well as increasing its total area (and cost).

Some recent semiconductor memory designs have proposed a stacked memory cell arrangement whereby the memory element and the transistor are vertically aligned as a pillar, or stack, above a base substrate. In a stacked memory cell, the drain and source regions are located one above the other, with the channel region extending vertically therebetween. While advantageously promoting an enhanced areal data density, it can be difficult to form the pillar structure of the vertical transistor so that the transistor can operate optimally.

### BRIEF SUMMARY

The present disclosure relates to a memory array that includes a plurality of non-volatile variable resistive memory cells where each memory cell is electrically connected to a vertical pillar transistor with an electrically conducting interconnect element. The electrically conducting interconnect element can reduce interface resistance and/or stress forces between the memory cell and the vertical pillar transistor. Methods of forming the same are also disclosed.

In one particular embodiment, a method includes providing a semiconductor wafer having a plurality of pillar structures extending orthogonally from the semiconductor wafer. An electrically conducting interconnect element is deposited onto at least selected vertical pillar transistors and a non-volatile variable resistive memory cell is deposited onto the electrically conducting interconnect layer to form a vertical transistor memory array.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 shows a functional block representation of an exemplary data storage device constructed in accordance with various embodiments of the present invention;

FIG. 2 is a schematic representation of a memory array of the device of FIG. 1;

FIG. 3 is a side elevational representation of various semiconductor layers of a vertically stacked memory cell of FIG. 2 in accordance with some embodiments;

FIGS. 4A-4B show prior art approaches to establishing bottom side interconnection to vertically stacked memory cells such as set forth in FIG. 3;

FIG. 5A shows an acceptor wafer constructed in accordance with some embodiments;

FIG. 5B shows a donor wafer constructed in accordance with some embodiments;

FIG. 6 shows a multi-wafer structure formed by attachment of respective conductive layers of the acceptor and donor wafers of FIGS. 5A-5B to form a combined conductive wafer embedded within the multi-wafer structure;

FIGS. 7A-7B provide respective side elevational and top plan views of the structure of FIG. 6 to which dots of photoresist (PR) material have been applied;

FIG. 8 represents application of an etching process to the structure of FIGS. 7A-7B to form a plurality of spaced apart stacked pillars of semiconductor material arranged into rows and columns;

FIGS. 9A-9B illustrate respective side elevation and top plan views of the application of masking material to form embedded control lines from the combined conductive layer within the structure;

FIG. 10 shows an elevational view of the resulting plurality of embedded control lines formed using the masking material of FIGS. 9A-9B;

FIG. 10A illustrates a side elevation view of a hardening implantation step;

FIG. 10B illustrates a side elevation view of a sacrificial oxide formation step;

FIG. 10C illustrates a side elevation view of a selective oxide etch step;

FIG. 10D illustrates a side elevation view of a gate oxide formation step;

FIGS. 11A-11D show a sequence in which gate structures are formed;

FIG. 12 illustrates a side elevation view of a low temperature silicide layer formation step;

FIG. 13A illustrates a side elevation view of a memory cell formation step;

FIG. 13B illustrates formation of a bit line step;

FIG. 14A illustrates a formation of via contacts step across the top side of the pillars of semiconductor material and memory cell formation step; and

FIG. 14B illustrates formation of memory cells and a bit line step.

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense. The definitions provided herein are to facilitate understanding of certain terms used frequently herein and are not meant to limit the scope of the present disclosure.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, and “on top”, if used herein, are utilized for ease of description to describe spatial relationships of an element(s) to another. Such spatially related terms encompass different orientations of the device in use or operation in addition to the particular orientations depicted in the figures and described herein. For example, if a cell depicted in the figures is turned over or flipped over, portions previously described as below or beneath other elements would then be above those other elements.

As used herein, when an element, component or layer for example is described as forming a “coincident interface” with, or being “on” “connected to”, “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as begin “directly on”, “directly connected to”, “directly coupled with”, or “directly in contact with” another element, there are no intervening elements, components or layers for example.

The present disclosure relates to a memory array that includes a plurality of non-volatile variable resistive memory cells and in particular, spin-torque transfer memory cells (i.e., STRAM) where each memory cell is electrically connected to a vertical pillar transistor with an electrically conducting interconnect element. The electrically conducting interconnect element reduces the interface resistance and/or reduces stress forces between the memory cell and the vertical pillar transistor. Since the vertical transistor is cylindrical, its total conductive surface is roughly 2πF, where F is the minimum feature size. By comparison, a horizontal transistor only scales as F. This means that vertical devices conduct roughly 6× the amount of current for a given area, enabling the memory cell to be scaled down to nearly 4 F2 (which is the theoretical minimum cell size). In addition a silicided interface provides the minimum parasitic contact resistance, and allows the device to be fully scalable with device size. In other words, the parasitic contact resistances are linear with devices size. Methods of forming the same are also disclosed. While the present disclosure is not so limited, an appreciation of various aspects of the disclosure will be gained through a discussion of the examples provided below.

The present disclosure is generally directed to an apparatus characterized as a multi-wafer structure with embedded (bottom side) control lines, and an associated method for making the same. The embedded control lines provide electrical interconnection with vertically stacked semiconductor elements within the multi-wafer structure. The stacked semiconductor elements form vertical pillar transistors that can be formed via a hardening implantation step as described below.

In various embodiments, an acceptor wafer is formed that incorporates various control circuitry, and a donor wafer is formed that incorporates a matrix from which individual channel based switching devices (e.g., vertical pillar transistors) are subsequently formed.

The acceptor wafer and the donor wafer are each provided with a metal layer on a respective facing surface. The acceptor and donor wafers are attached to form the multi-wafer structure, and during this attachment process the respective metal layers are brought together to form a single combined metal layer that is embedded within the multi-wafer structure. The combined metal layer is transformed during subsequent processing into individual embedded bottom side control lines (e.g., embedded source lines).

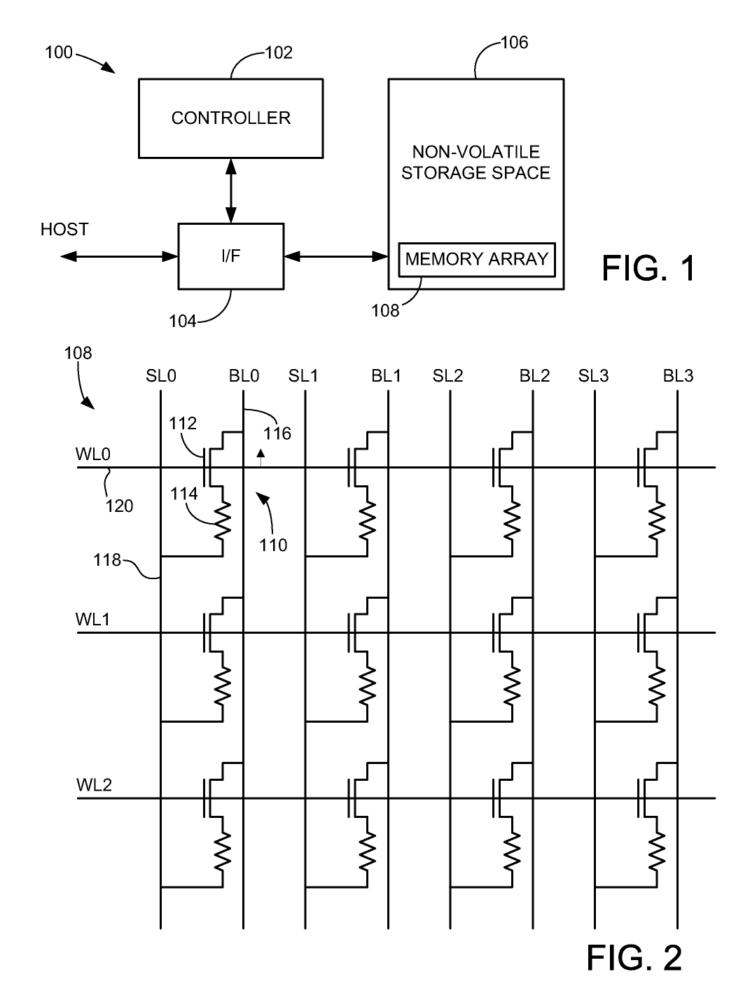

FIG. 1 provides an illustrative device environment in which such processing can be advantageously utilized. In FIG. 1, a data storage device 100 employs semiconductor memory to store data supplied by a host. In some embodiments, the device 100 is characterized as a non-volatile solid state drive (SSD), although such is not limiting. In many embodiments, the device 100 is characterized as a volatile dynamic random access memory (DRAM), non-volatile resistive random access memory (RRAM), and non-volatile spin-torque transfer random access memory (STRAM).

A programmable controller 102 provides top level control of the device 100 during operation. An interface circuit (I/F) 104 communicates with the host and transfers data to be stored in a semiconductor memory 106.

The semiconductor memory 106 is characterized as a non-volatile storage space formed from one or more arrays 108 of non-volatile memory cells (e.g., RRAM or STRAM. In other embodiments, the memory 106 can take the form of a volatile memory space such as a DRAM cache. Additional hierarchical memory storage layers can be provided such as a downstream non-volatile main storage (e.g., a magnetic disc, etc.).

FIG. 2 is a schematic representation of a portion of the non-volatile array 108 of FIG. 1. The array 108 is formed from a number of memory cells 110 arranged into rows and columns. While only three (3) rows and four (4) columns are shown in FIG. 2, it will be appreciated that any numbers of rows and columns of the cells 110 can be provided.

Each cell 110 in the array 108 includes a switching device 112 connected in series with a resistive memory element 114. In some embodiments, the switching devices 112 are characterized as n-channel MOSFETs (transistors), and the memory elements 114 are programmable resistive sense elements such as but not limited to resistive random access memory (RRAM) elements, spin-torque transfer random access memory (STRAM) elements or programmable metallization cells (PMCs).

A number of bit lines 116 denoted as BL0-BL3 interconnect a first end (“top side”) of each of the cells along each column. Source lines 118 denoted as SL0-SL3 interconnect an opposing, second end (“bottom side”) of each of the cells along each column. Word lines 120 denoted as WL0-WL2 interconnect the gate regions of the MOSFETs 112 along each row. It will be appreciated that other arrangements and interconnection schemes can be employed, so that the schematic representation of FIG. 2 is merely illustrative and not limiting.

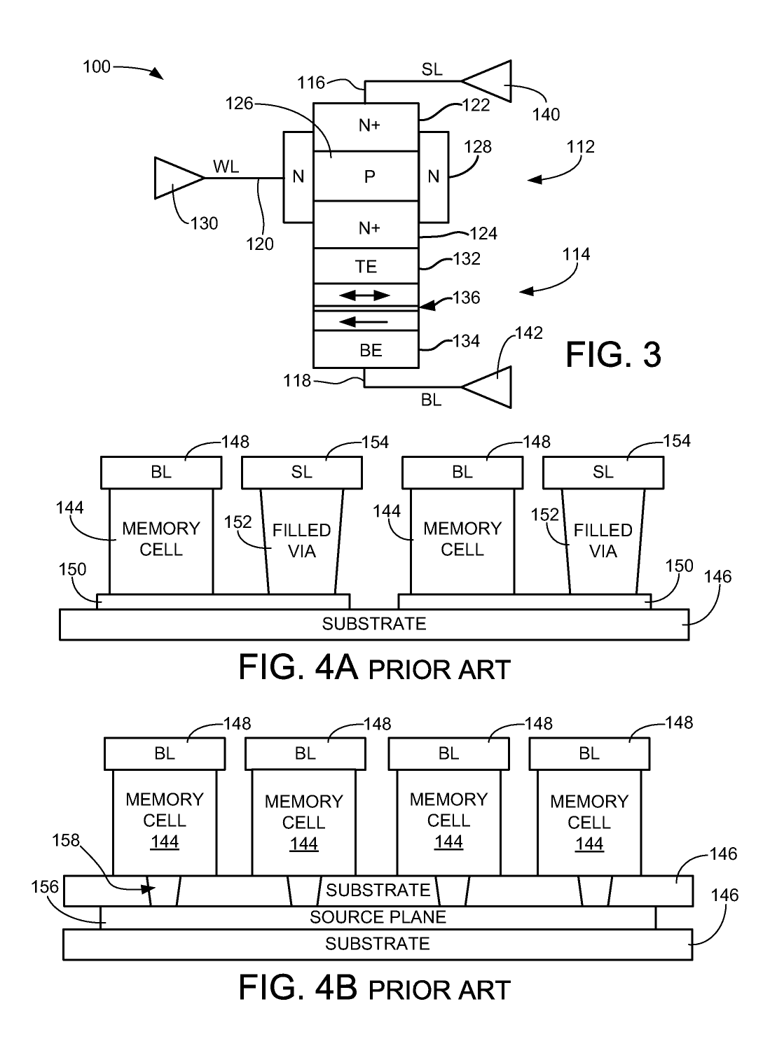

FIG. 3 is a layer representation of a selected memory cell 110 from FIG. 2 in accordance with some embodiments. The transistor 112 is formed from respective N+ doped regions 122, 124 separated by a vertically extending P doped channel region 126. An N doped control gate 128 surrounds the channel region 126 (a gate oxide layer, not shown here, separates the N doped control gate 128 from the N+ doped regions 122, 124 and P doped channel region 126). Application of a suitable bias voltage from a word line (WL) driver 130 will place the transistor 112 in a forward biased (conductive) state, allowing currents to pass through the memory cell 110 across the drain-source junction.

The memory element 114 is characterized in FIG. 3 as an RRAM or STRAM element and includes top and bottom electrodes (TE, BE) 132, 134 separated by a magnetic tunnel junction 136. The magnetic tunnel junction 136 includes a magnetic free layer (double arrow layer) and a magnetic pinned layer (single arrow layer) separated by a tunnel barrier layer. The STRAM 136 cell is programmed by passing a spin polarized write current through the STRAM 136 cell in a first or second direction.

To program the memory cell 110 to a desired state, the WL driver 130 will assert the WL 120 and respective SL and BL drivers 140, 142 will direct current through the memory element 114 in the appropriate direction and at the appropriate voltage and current magnitudes. The programmed state of the element 114 can be subsequently read by asserting the WL 120, passing a smaller read bias current through the memory cell 110 such as from SL driver 140 to BL driver 142, and comparing the resulting voltage on the SL 116 to a reference voltage using a separate sense amplifier (not shown).

The stacked nature of the memory cell 110 in FIG. 3 provides a number of advantages. The relatively small areal extent of the memory cell allows arrays such as in FIG. 2 to achieve relatively high areal densities. However, a limitation with stacked memory cells such as set forth in FIG. 3 relates to establishing access to the bottom side of the memory cell; that is, it has been found difficult to establish an electrical interconnection such as that shown in FIG. 3 between the BL driver 142 and the BE 134.

One prior art solution uses filled via structures such as depicted in FIG. 4A. In this approach, individual stacked memory cells 144 are supported above a base substrate 146, and bit lines 148 are connected to the tops of the memory cells 144. Bottom-side connections can be made using embedded conductive pads 150 and vias 152 that are disposed adjacent the memory cells 144 and filled with a conductive material. Source lines 154 are connected to the top sides of the vias 152, so that the source lines run adjacent the bit lines 148 across the top of the array.

While operable, it can be appreciated that the approach in FIG. 4A reduces areal density of the array due to the additional space required for the filled vias 152. The approach in FIG. 4A may further require enhanced manufacturing complexities and costs to form the vias and the conductive pad interconnections.

Another prior art solution that has been employed with stacked cells is the use of a common source plane (SP), such as depicted at 156 in FIG. 4B. The source plane 156 extends below the respective stacked memory cells 144 so that all of the memory cells in the array are interconnected to the source plane, such as through vias 158 that extend through an upper oxide substrate 146. As before, individual rows (or columns) of the memory cells are interconnected via separate bit lines 148.

While operable, limitations with FIG. 4B include the enhanced processing and cost to form the metallization of the entire source plane, as well as limitations during operation in that currents generally cannot be passed through two or more cells concurrently in opposing directions. Other prior art solutions include additional interconnection layers and contact layers to accommodate the bottom side interconnections for the stacked memory cells.

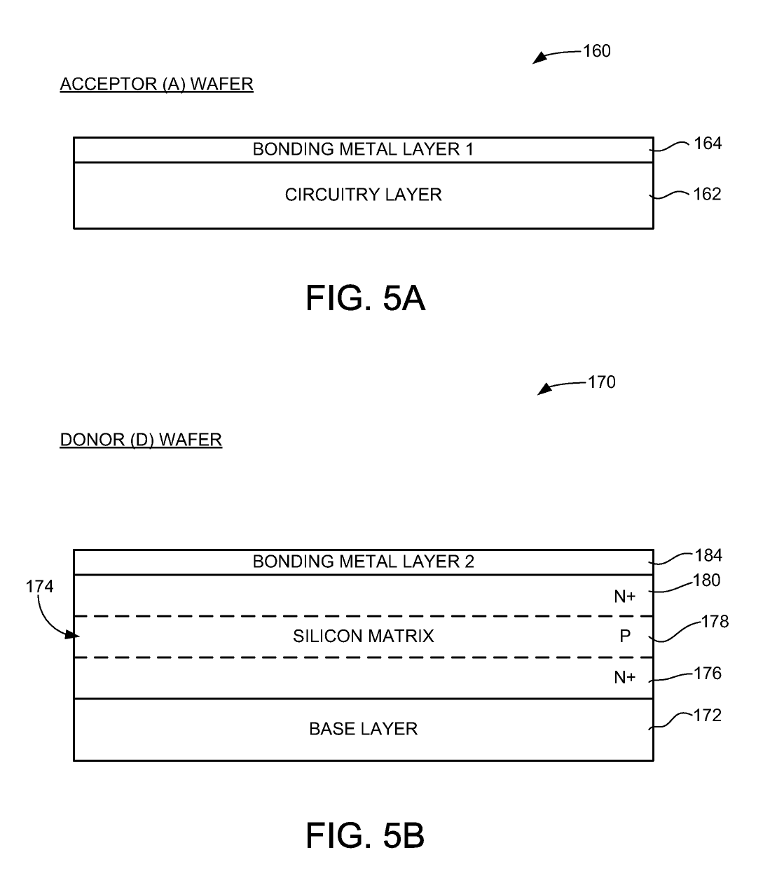

Accordingly, various embodiments of the present invention are generally directed to a manufacturing process that efficiently and easily forms bottom-side control lines (e.g., source lines) for an array of vertically stacked memory cells. To illustrate such processing, reference is first made to FIGS. 5A and 5B which respectively show an acceptor (A) wafer 160 and a donor (D) wafer 170. In some embodiments, the wafers 160, 170 are silicon based substrates which are separately formed with a number of initial, respective features.

The acceptor wafer 160 includes a circuit layer 162 in which various control circuits, including CMOS circuitry, are formed during prior processing. This circuitry may include the various drivers shown in FIG. 3, as well as other control circuitry used in conjunction with the cells 110. The circuit layer 162 may also include contacts for the various vertical transistors. A first conductive metal layer 164 is formed on a top facing surface of the circuit layer 162. The metal layer 164 can be formed of any suitable metals or metal alloys. As desired, the metal layer can include multiple layers of conductive and dielectric materials, and provides a relatively low resistance per unit length.

The donor wafer 170 includes a number of layers including a base layer 172, which may be a bulk oxide. A doped silicon matrix 174 is formed in the base layer, and includes regions 176, 178 and 180 of respective NPN doping levels to ultimately form the respective drain, source and channel regions 122, 124 and 126 in FIG. 3. The doped regions can be formed using ion implantation or other techniques. A second conductive metal layer 184 is formed on a top facing surface of the doped silicon matrix 174. The material composition of the second metal layer 184 may be the same, or different from, the first metal layer 164.

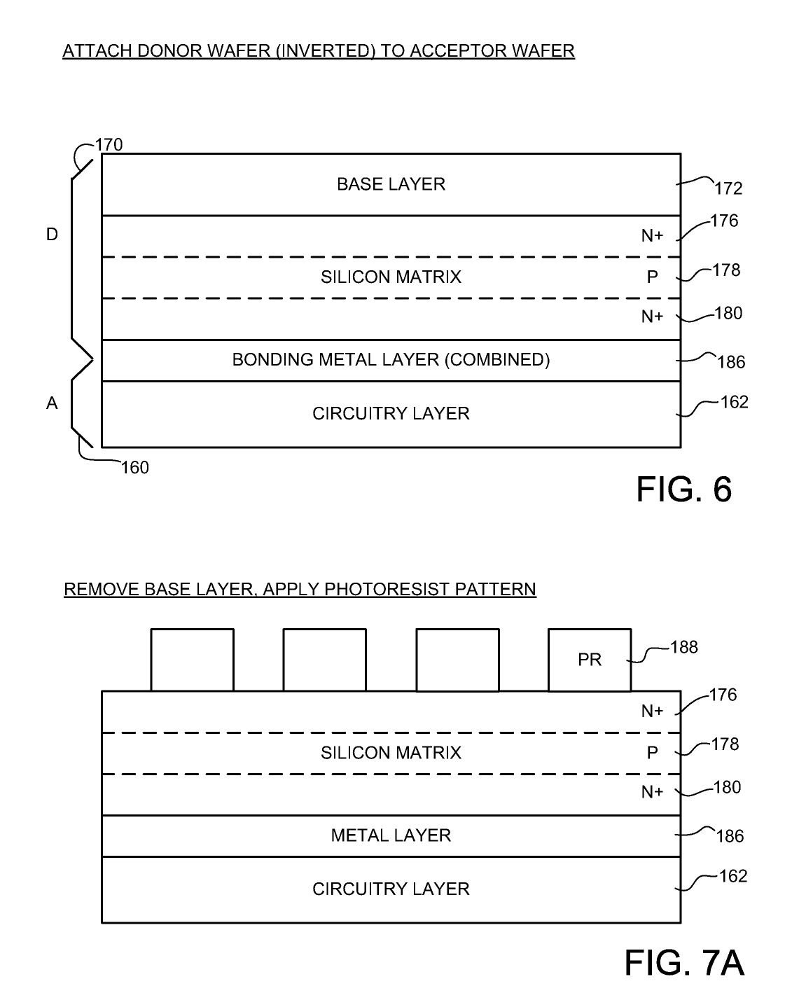

The respective wafers 160, 170 are mated as shown in FIG. 6 to form a multi-wafer structure. The donor wafer 170 is inverted relative to the acceptor wafer 160 and the first and second metal layers 164, 184 are bonded together to provide a combined metal layer 186. Any number of suitable bonding processes can be utilized, including reflow heating. Additional materials can be introduced to establish the metalized layer 186 interconnection during the bonding process.

As will become apparent from the following discussion, the individual control (source lines) are eventually formed from this metal layer 186, so the metal layer can be characterized as a planar extent of conductive material with a substantially uniform thickness and overall length and width dimensions substantially corresponding to the overall length and width dimensions of the multi-wafer structure. In this way, the finished control lines will fully extend across the array in parallel, spaced apart fashion in the desired direction (e.g., in the row direction or the column direction, as required).

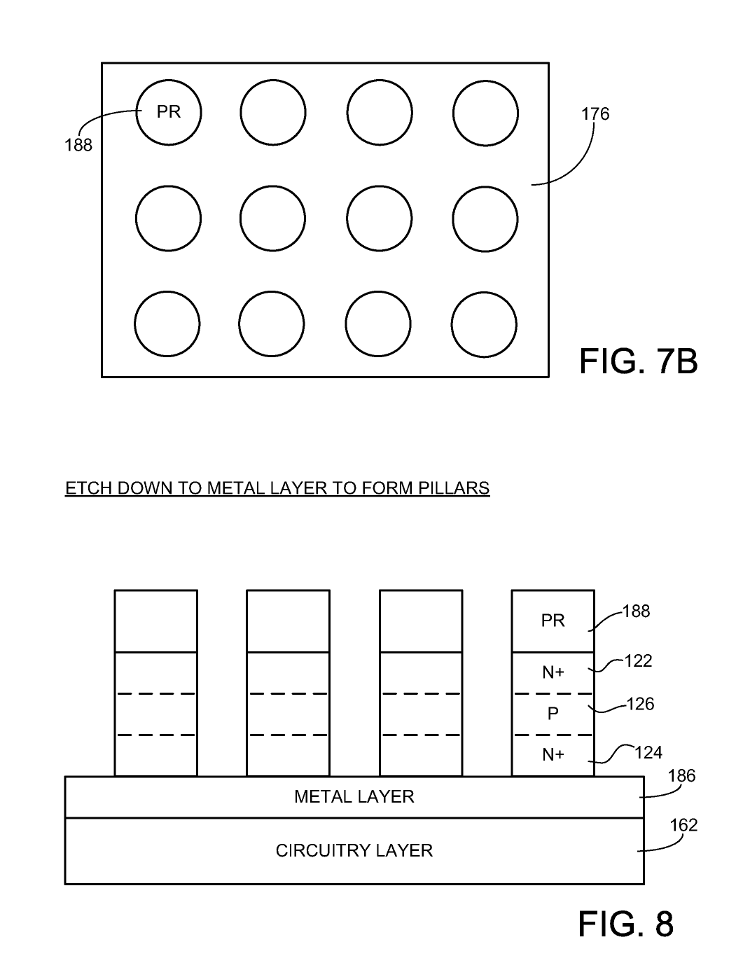

The base oxide layer 172 is removed and localized areas (dots) of photoresist (PR) 188 are applied to the top of the silicon matrix, as shown in FIGS. 7A-7B. The dots of PR 188 are circular in shape in the illustrated embodiment to provide a cylindrical cross-sectional shape for the cells, although other cross-sectional shapes can be alternatively provided. An etching process is next carried as set forth by FIG. 8, which removes all of the material not covered by the dots of PR 188 down to the metal layer 186. At the end of this etching process, spaced apart pillars, or vertical stacks, of layers will be left which correspond to the individual memory cells as set forth in FIG. 3.

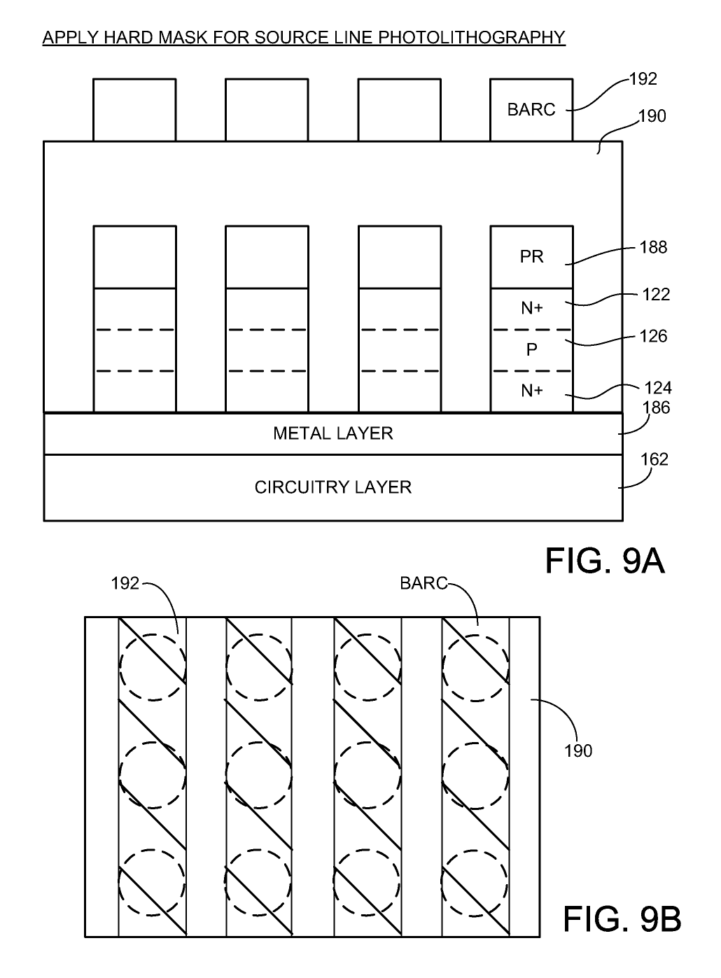

A hard mask is applied as shown in FIGS. 9A-9B to form the individual control (source) lines. Organic material 190 is deposited between the layers and, as desired, a bottom antireflective coating (BARC) or other photolithography masking material 192 can be applied to aid the process. The masking material 192 extends across the top of the organic material 190 over the respective stacks as depicted in cross-hatched fashion in FIG. 9B.

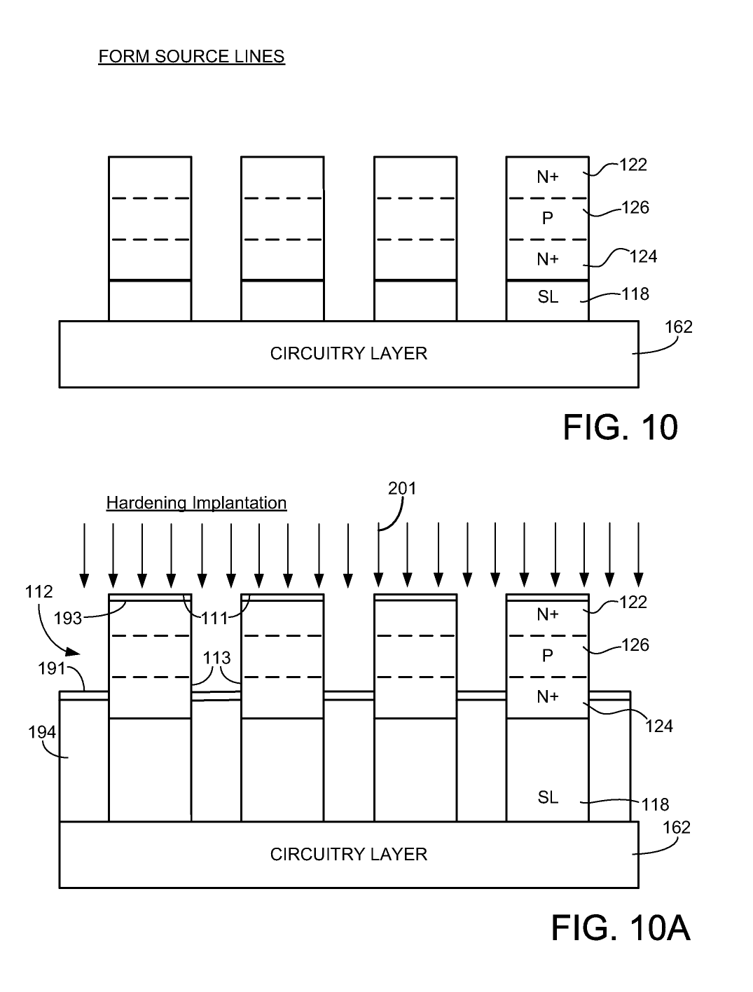

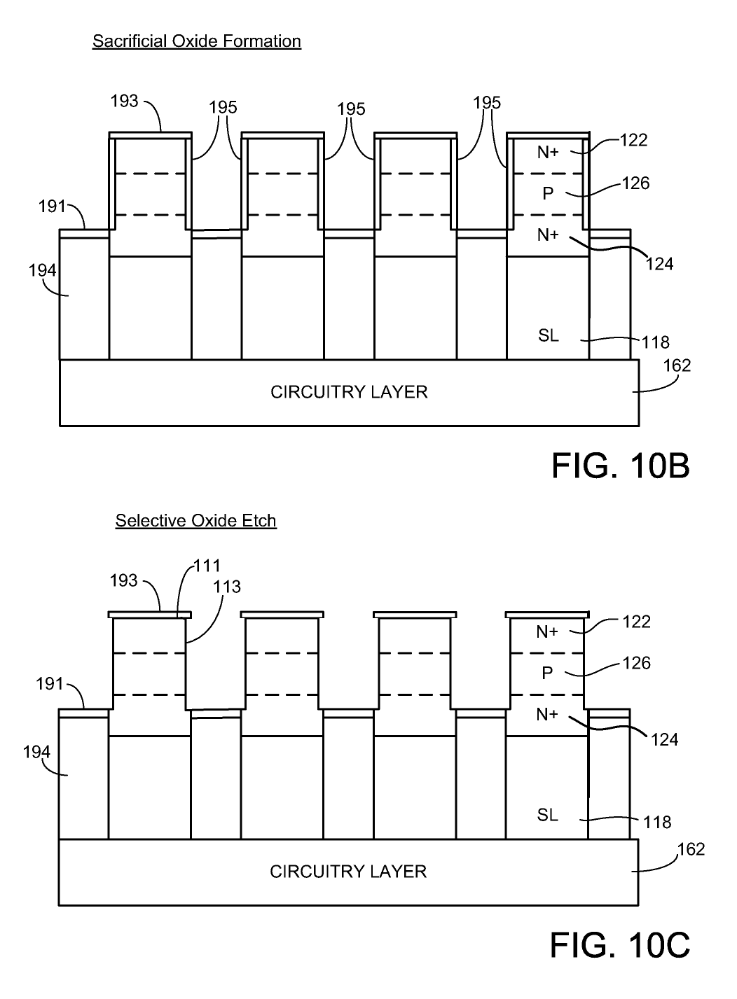

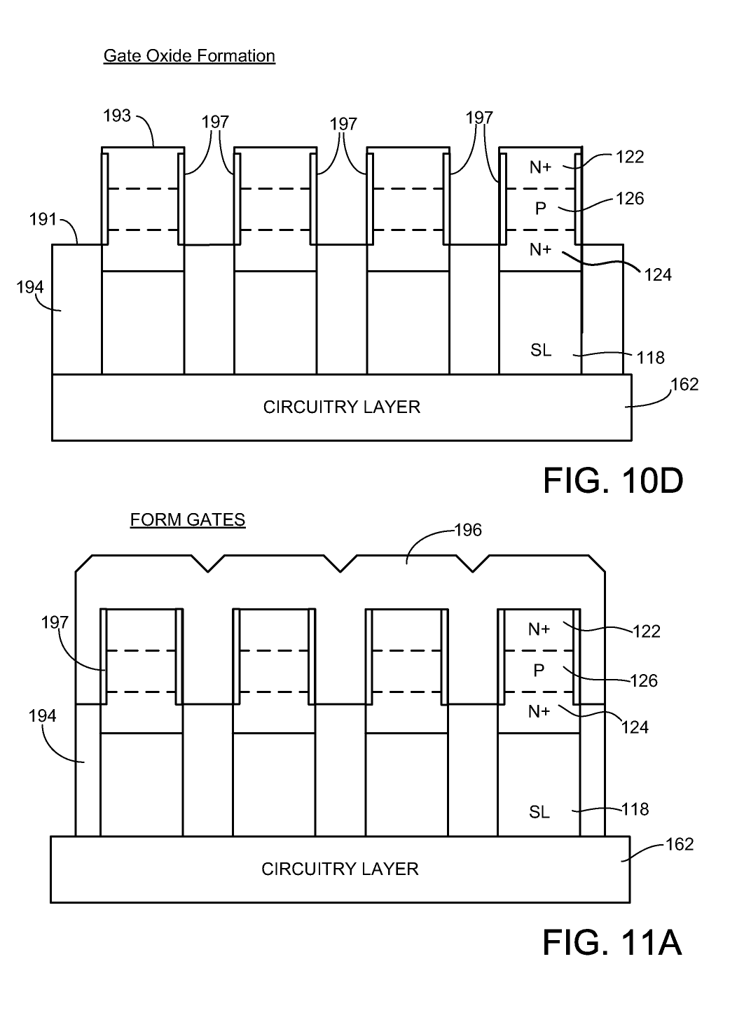

An etching process is carried out in FIG. 10 to form the source lines 118. The etching removes the organic material and portions of the conductive layer 186 down to the underlying circuitry layer 162, so that the resulting source lines run under the columns of stacks as shown in FIG. 9B. The photoresist PR 188, organic material 190 and masking material 192 on the top of each stack are also removed at this point.

FIG. 10A illustrates a side elevation view of a hardening implantation step. FIG. 10B illustrates a side elevation view of a sacrificial oxide formation step. FIG. 10C illustrates a side elevation view of a selective oxide etch step. FIG. 10D illustrates a side elevation view of a gate oxide formation step. These steps allow the preferential rounding of the vertical pillar transistor side surfaces while maintaining a sharp edge with the vertical pillar top surface. These features improve the performance of the vertical pillar transistor.

An underlying dielectric material, such as an oxide 194, is deposited around the bases of the stacks or plurality of pillar structures up to the desired height. The plurality of pillar structures extends orthogonally from the semiconductor wafer or circuitry layer 162.

Each pillar structure will form a vertical pillar transistor 112 having a top surface 111 and a side surface 113 orthogonal to the top surface. The top surface 111 is generally planar and parallel with the major surface of the semiconductor wafer or circuitry layer 162. In many embodiments the cross-sectional or top view shape of the pillar structure includes sharp angles where the sides surfaces of the pillar structure intersect. These sharp angles can decrease the performance of the formed vertical pillar transistor 112. Thus rounding these sharp edges or corners is desired.

One illustrative method of rounding these sharp edges or corners of the side surfaces of the pillar structure is to implant a hardening species into the vertical pillar transistor top surface and not in the vertical pillar transistor side surface(s). The hardening implant step implants a particular ion (e.g., nitrogen) into the semiconductor material surface (e.g., silicon) so that when that implanted semiconductor material surface is oxidized, it forms an oxide that includes the implanted ion (e.g, silicon oxynitride). The remaining non-implanted surfaces will form a different oxide species upon the oxidation step. Then the two different oxide layers can be preferentially removed utilizing an appropriately oxide selective removal or etching step.

As illustrated in FIG. 10A, a hardening implantation 201 directs an implantation ion into the vertical pillar top surfaces 111 and the parallel exposed oxide 194 surfaces that was deposited up to a desired height of the vertical pillars. The implantation step forms ion (e.g., nitrogen) implanted surfaces 193 and 191 that will form a first oxide layer (e.g., silicon oxynitride) upon oxidation.

FIG. 10B illustrates the formation of the sacrificial oxide formation. The vertical pillar transistor is oxidized to form a top surface oxide material layer 193 and a side surface oxide material layer 195. The top surfaces oxide material layer 193 is different than the side surface oxide material layer 195 due to the hardening implantation step.

FIG. 10C illustrates a side elevation view of a selective oxide etch step. The selective etch step preferentially removes the side surface oxide layer 195 to form a vertical pillar transistor having rounded side surfaces. For example, if the hardening implantation ion is nitrogen, the oxidation step will form a silicon oxynitride layer 193, 191 on the top surfaces 111 and a silicon oxide layer 195 on the sides surfaces 113. The silicon oxide layer 195 on the sides surfaces 113 can be selectively etched relative to the silicon oxynitride layer 193, 191 on the top surfaces 111. The oxide formation and selective etching of the sides surfaces 113 functions to round out the side surfaces 113 of the vertical pillar while the corner or edge where the top surface 111 meets the side surface 113 remains a sharp or non-rounded intersection of the two surfaces 111 and 113.

FIG. 10D illustrates a side elevation view of a gate oxide formation step. A gate oxide layer 197 can then be formed on the rounded side surfaces 113 of the vertical pillar. Forming the gate oxide layer 197 can further enhance the rounding of the side surfaces 113 of the vertical pillar forming a rounded gate oxide surfaces of the vertical pillar structure.

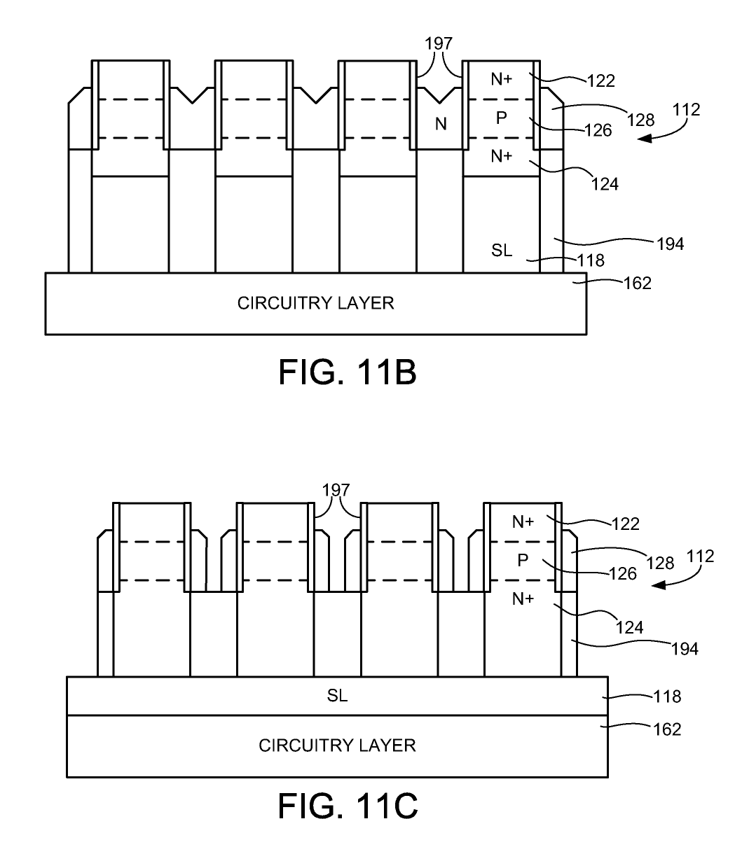

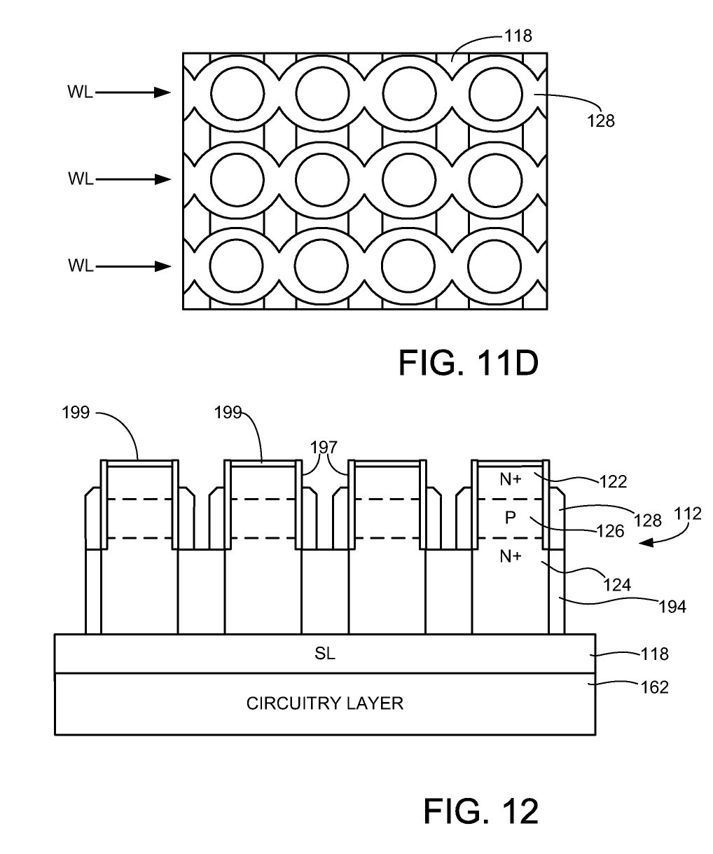

FIGS. 11A-11D show a sequence in which gate structures are formed on the rounded gate oxide surfaces of the vertical pillar structure. An appropriate semiconductor gate material 196 such as silicon is deposited on top of the oxide 194 to fully enclose the stacks or vertical pillar structures, as shown in FIG. 11A. The semiconductor material can be doped via ion implantation at this time. A suitable masking and etching process removes the semiconductor material down to form the gate structures as generally depicted at 128 in FIG. 3. FIG. 11B shows a row of the cells; FIG. 11C shows a column of the cells; and FIG. 11D shows a top plan representation of the cells. As can be seen from these drawings, the gate structures 128 are interconnected along each row to form the aforementioned word lines 120, and the gate structures of each selected row are electrically isolated from those of the adjacent rows. Also the vertical transistors in the rows are closer to each other than the vertical transistors in the columns so that the gate structures are self-aligned and connected to each other along each row.

FIG. 12 illustrates a side elevation view of a low temperature silicide layer formation step. Following the formation of the gate structures 128 on the vertical pillar transistors 112, a silicide layer 199 is deposited on the top surface of the vertical pillar transistors 112. The silicide layer 199 aides in reducing an interface resistance between the vertical pillar transistors 112 and the memory cell (formed as described below). The silicide layer 199 is generally described as an electrically conducting interconnect element.

The silicide layer 199 can be formed of any useful silicide material that can assist in reducing interface resistance. In many embodiments the silicide layer 199 is a cobalt disilicide material or a nickel disilicide material. The silicide layer 199 can be formed using any useful process that does not degrade the properties of the vertical pillar transistors 112. In particular, the silicide layer 199 can be formed with a chemical vapor deposition process at a temperature that is less than 400 degrees centigrade or from 200 to 375 degrees centigrade. Then the silicide layer 199 can be annealed to diffuse the silicide layer 199 into the surface of the vertical pillar transistors 112 and to react all unreacted ferromagnetic materials on the siliscon surface. In many embodiments, the anneal temperature is less than 525 degrees centigrade or less than 500 degrees centigrade or less than 450 degrees centigrade or less than 400 degrees centigrade. One illustrative silicide layer deposition process is described in U.S. Pat. No. 6,346,477 which is incorporated by reference herein.

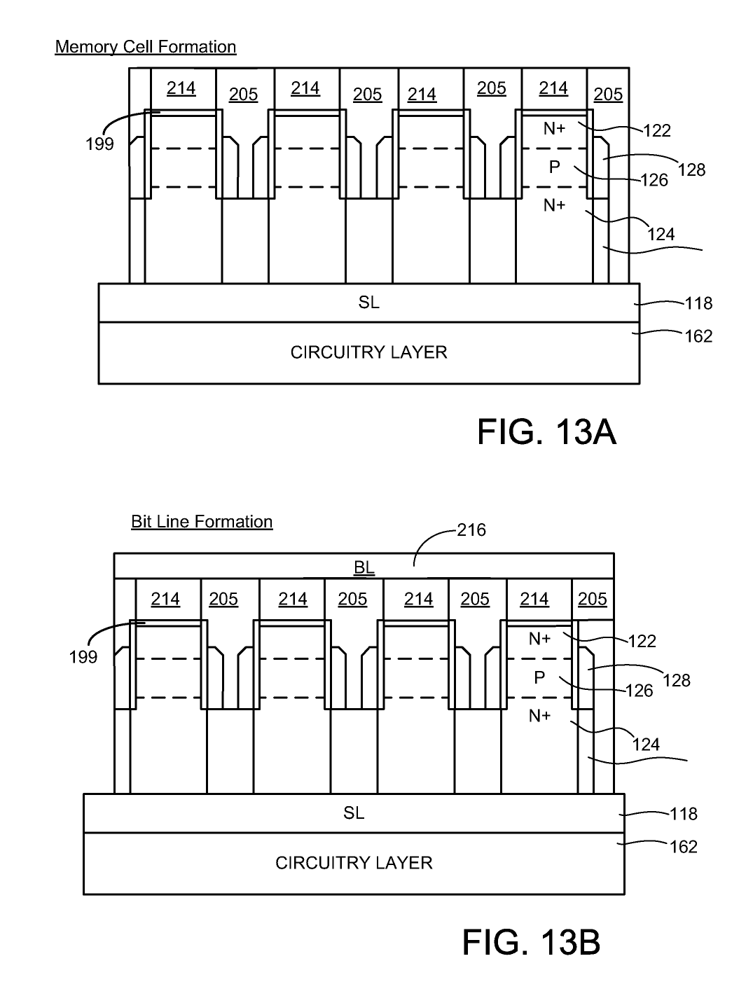

FIG. 13A illustrates a side elevation view of a memory cell 214 formation step. Then a memory cell 214 is deposited onto the silicide layer 199 utilizing known semiconductor techniques. The memory cell 214 is a non-volatile variable resistive memory cell such as a STRAM or RRAM memory cell, as described above. The memory cell 214 can be electrically isolated from each other by an insulating material 205 such as silicon oxide.

The memory cell 214 can have a similar cross-sectional shape as the vertical pillar transistor 112. In many embodiments the memory cell 214 and the vertical pillar transistor 112 are in vertical registration and both have a circular cross-sectional shape. In other embodiments, the memory cell 214 and the vertical pillar transistor 112 are in vertical registration and the vertical pillar transistor 112 has a circular cross-sectional shape and the memory cell 214 has an elliptical cross-sectional shape.

FIG. 13B illustrates formation of a bit line BL step. A bit line BL is deposited onto the memory cells 214. The deposited bit line material forms a layer of uniform thickness that covers the length and width dimensions of the overall array. Suitable masking and etching processing (not separately depicted) removes portions of this material to form the parallel, spaced apart bit lines 216. It is noted that in this embodiment the bit lines 216 and source lines 118 are parallel and orthogonal to the word lines 120, corresponding to the schematic depiction of FIG. 2. The processing disclosed herein can provide other arrangements and orientations of these respective control lines as required.

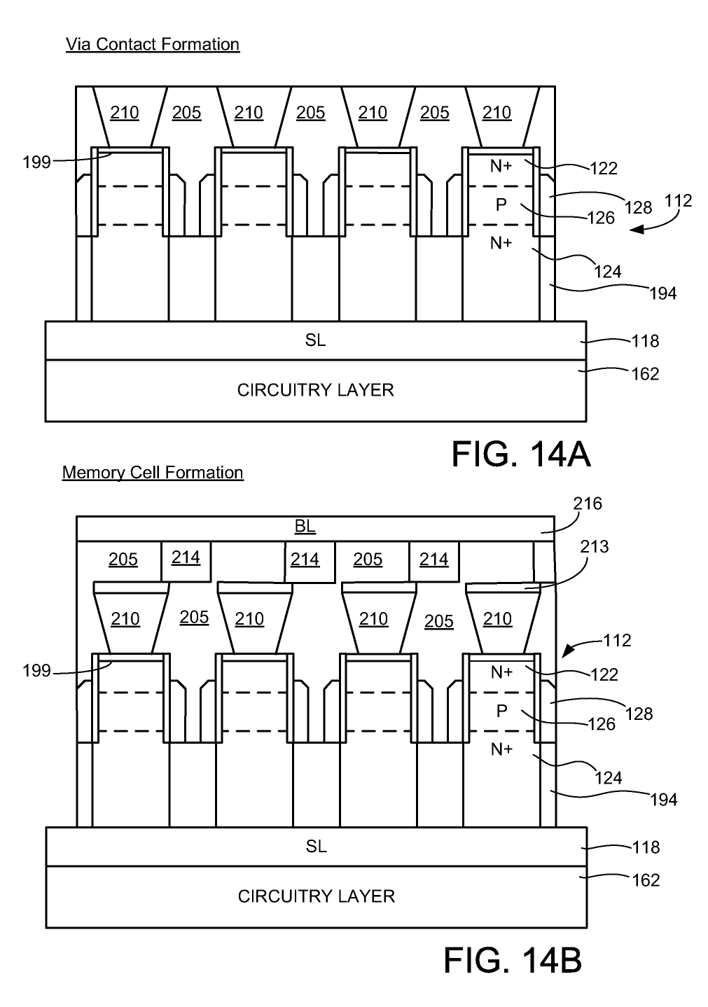

FIG. 14A illustrates a formation of via contacts step across the top side of the pillars of semiconductor material and in particular the silicide layer 199. An electrically insulating oxide material 205 is deposited onto the silicide layer 199. The electrically insulating material 205 can be any useful oxide such as, silicon dioxide for example. Then vias are etched into the electrically insulating oxide material 205 and the vias are filled with electrically conducting material to form electrically conducting interconnect elements 210. The vias can be formed in the oxide material 205 and filled with conductive material using a physical vapor deposition or other suitable process, for example. The electrically conducting material can be any useful material such as tungsten, or aluminum for example. As illustrated, the electrically conducting interconnect elements 210 are electrically isolated from each other by the electrically insulating material 205.

FIG. 14B illustrates formation of memory cells and a bit line step. A bottom electrode layer 213 is deposited onto the electrically conducting interconnect elements 210 and electrically insulating oxide material 205. This layer is patterned to form the illustrated bottom electrode layer 213 elements.

Then a memory cell 214 is deposited onto the bottom electrode layer 213 utilizing known semiconductor techniques. The memory cell 214 is a non-volatile variable resistive memory cell such as a STRAM or RRAM memory cell, as described above. The memory cell 214 is offset (i.e., vertically offset) from the vertical pillar transistor 112 and the electrically conducting interconnect element 210. It is believed that a top surface of the electrically conducting interconnect element 210 is a concave surface and thus offsetting the memory cell 214 from the top surface of the electrically conducting interconnect element 210 can help reduce interface stress forces between the memory cell 214 from the top surface of the electrically conducting interconnect element 210.

The memory cell 214 can have a similar cross-sectional shape as the vertical pillar transistor 112. In many embodiments the vertical pillar transistor 112 has a circular cross-sectional shape and the memory cell 214 has a circular cross-sectional shape. In other embodiments, the vertical pillar transistor 112 has a circular cross-sectional shape and the memory cell 214 has an elliptical cross-sectional shape. The elliptical cross-sectional shape of the memory cell 214 can assist in reducing the surface area needed for the memory array.

A bit line BL is deposited onto the memory cells 214. The memory cell 214 is electrically connected to the corresponding electrically conducting interconnect element to form a vertical transistor memory array, as illustrated.

The deposited bit line material forms a layer of uniform thickness that covers the length and width dimensions of the overall array. Suitable masking and etching processing (not separately depicted) removes portions of this material to form the parallel, spaced apart bit lines 216. It is noted that in this embodiment the bit lines 216 and source lines 118 are parallel and orthogonal to the word lines 120, corresponding to the schematic depiction of FIG. 2. The processing disclosed herein can provide other arrangements and orientations of these respective control lines as required.

By forming the memory cell 214 subsequently to forming the vertical pillar transistor 112 provides several advantages. The memory cell 214 and the vertical pillar transistor 112 can each possess a different cross-sectional shape. For example, the memory cell 214 can have an elliptical shape and the vertical pillar transistor 112 can have a cylindrical shape. The elliptical shape can be orientated at an angle relative to the both the source line and bit line, such as an angle from 40 to 50 degrees, or 45 degrees. This configuration can allow for an increased density of memory cells in the array.

It will now be appreciated that the various embodiments as presented herein provide a number of advantages over the prior art. Spaced apart bottom side control lines can be easily and efficiently formed during manufacturing, eliminating the need for additional interconnections and conductive layers. Unlike top side interconnection techniques, the present process allows the source lines to run independently of the bit lines. Enhanced data densities can be achieved and multiple concurrent access operations can be carried out on different parts of the array, as desired.

Thus, embodiments of the VERTICAL TRANSISTOR STRAM ARRAY are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present invention is limited only by the claims that follow.

What is claimed is:

1. A method comprising:
providing a semiconductor wafer having a plurality of pillar structures extending orthogonally from the semiconductor wafer, each pillar structure forming a vertical pillar transistor having a top surface and a side surface orthogonal to the top surface;
depositing an electrically conducting interconnect element onto at least selected vertical pillar transistor top surfaces; and
depositing a non-volatile variable resistive memory cell onto the electrically conducting interconnect layer to form a vertical transistor memory array.

2. The method according to claim 1 wherein adjacent non-volatile variable resistive memory cells are electrically isolated from each other.

3. The method according to claim 1 wherein adjacent electrically conducting interconnect elements are electrically isolated from each other with an oxide material.

4. The method according to claim 1 wherein the depositing an electrically conducting interconnect element step comprises depositing an silicide layer at a deposition temperature of less than 400 degrees centigrade onto at least selected vertical pillar transistor top surfaces.

5. The method according to claim 1 wherein the top surface is a parallel with the major surface of the semiconductor wafer.

6. The method according to claim 1 wherein the non-volatile variable resistive memory cell has an elliptical cross-sectional shape and the vertical pillar transistor has a circular cross-sectional shape.

7. The method according to claim 1 wherein the non-volatile variable resistive memory cell has a circular cross-sectional shape and the vertical pillar transistor the vertical pillar transistor has a circular cross-sectional shape.

8. The method according to claim 1 wherein the non-volatile variable resistive memory cell comprises a spin-torque transfer memory cell.

9. The method according to claim 7 wherein vertical pillar transistors are in registration with the non-volatile variable resistive memory cell.

10. The method according to claim 1 further comprising depositing a bit line onto a selected row or column of the non-volatile variable resistive memory cells.

11. The method according to claim 4 wherein silicide layer electrically connects and separates the vertical pillar transistors that are in registration with the non-volatile variable resistive memory cells.

12. A method comprising:
providing a semiconductor wafer having a plurality of pillar structures extending orthogonally from the semiconductor wafer, each pillar structure forming a vertical pillar transistor having a top surface and a side surface orthogonal to the top surface;
depositing an oxide material layer onto the top surface of the vertical pillar transistors;
etching vias into the oxide material layer, wherein each via is in registration with a selected top surface of the vertical pillar transistors;
depositing an electrically conducting interconnect element into at least selected vias; and
depositing a non-volatile variable resistive memory cell onto the electrically conducting interconnect layer to form a vertical transistor memory array.

13. The method according to claim 12 wherein the top surface is a parallel with the major surface of the semiconductor wafer.

14. The method according to claim 12 wherein at least selected non-volatile variable resistive memory cell are electrically connected to at least selected vertical pillar transistor and at least selected non-volatile variable resistive memory cells are offset from at least selected vertical pillar transistors.

15. The method according to claim 12 wherein the non-volatile variable resistive memory cell has a circular cross-sectional shape and the vertical pillar transistor has a circular cross-sectional shape.

16. The method according to claim 12 wherein the non-volatile variable resistive memory cell has an elliptical cross-sectional shape.

17. The method according to claim 12 wherein the memory cell comprises a spin-torque transfer memory cell.

18. The method according to claim 12 further comprising depositing a silicide layer at a deposition temperature of less than 400 degrees centigrade onto at least selected vertical pillar transistor top surfaces before the depositing an oxide material layer step.

19. A method comprising:
providing a semiconductor wafer having a plurality of pillar structures extending orthogonally from the semiconductor wafer, each pillar structure forming a vertical pillar transistor having a top surface and a side surface orthogonal to the top surface;
depositing a silicide layer at a deposition temperature of less than 400 degrees centigrade onto at least selected vertical pillar transistor top surfaces; and
depositing a non-volatile variable resistive memory cell onto the silicide layer to form a vertical transistor memory array.

20. The method according to claim 19 wherein the memory cell comprises a spin-torque transfer memory cell.

21. A memory array comprising:
a semiconductor wafer having a plurality of pillar structures extending orthogonally from the semiconductor wafer, each pillar structure forming a vertical pillar transistor having a top surface and a side surface orthogonal to the top surface;
a plurality of memory cells, wherein at least selected memory cells have a cross-sectional shape that is vertically offset from the vertical pillar transistor and in electrical connection with the vertical pillar transistor; and
a silicide layer between the memory cell and the vertical pillar transistor.

22. The memory array according to claim 21, wherein the memory cell is an STRAM cell.

23. The memory array according to claim 21, further comprising an electrically conducting interconnect element disposed onto the vertical pillar transistor having a top surface and the memory cells have a cross-sectional shape that is electrically connected to and vertically offset from the electrically conducting interconnect element.

24. The memory array according to claim 21, wherein the memory cell has an elliptical cross-sectional shape.

25. The memory array according to claim 21, wherein the memory cell is orientated at an angle relative from 40 to 50 degrees to a source line and a bit line.
